(19) United States
(12) Patent Application Publication
(10) Pub. No.: US 2026/0114143 A1
(43) Pub. Date: Apr. 23, 2026

(54) DISPLAY DEVICE

(71) Applicant: Magnolia White Corporation, Tokyo (JP)

(72) Inventors: Takamitsu FUJIMOTO, Tokyo (JP); Kenji HARADA, Tokyo (JP); Takayuki SUZUKI, Tokyo (JP)

(73) Assignee: Magnolia White Corporation, Tokyo (JP)

(21) Appl. No.: 19/363,678

(22) Filed: Oct. 21, 2025

(30) Foreign Application Priority Data
Oct. 22, 2024 (JP) 2024-185730

(51) Int. Cl. H10K 59/131; H10K 59/122

(52) U.S. Cl. CPC H10K 59/131; H10K 59/122

(57) ABSTRACT

According to one embodiment, a display device includes a display area and a peripheral area on an outer side of the display area, a plurality of scanning lines extending along a first direction and arranged along a second direction intersecting the first direction, a first semiconductor layer disposed in the display area and overlapping a respective one of the plurality of scanning lines, and a second semiconductor layer disposed in the peripheral area and overlapping one of the plurality of scanning lines, and the second semiconductor layer includes a first dummy semiconductor patterned into a shape of an identification symbol.

### CROSS-REFERENCE TO RELATED APPLICATIONS

This application is based upon and claims the benefit of priority from Japanese Patent Application No. 2024-185730 filed on Oct. 22, 2024, the entire contents of which are incorporated herein by reference.

### FIELD

Embodiments described herein relate generally to a display device.

### BACKGROUND

In recent years, display devices in which organic light-emitting diodes (OLEDs) are applied as display elements have been put into practical use. In display devices of this type, technology for achieving narrow frame design is required.

### BRIEF DESCRIPTION OF THE DRAWINGS

FIG. 1 is a diagram showing a configuration example of a display device according to one embodiment.

FIG. 2 is a circuit diagram showing a configuration example applicable to a pixel circuit provided for each subpixel.

FIG. 3 is a plan view schematically showing an example of layout of subpixels.

FIG. 4 is a cross-sectional view schematically showing the display device taken along the line IV-IV in FIG. 3.

FIG. 5 is a cross-sectional view schematically showing an example of a layer configuration applicable to a circuit layer.

FIG. 6 is a diagram showing a configuration example of a transistor contained in the circuit layer.

FIG. 7 is a plan view schematically showing an example of the boundary between a display area and a peripheral area.

FIG. 8 is a cross-sectional view schematically showing the display device taken along the line VIII-VIII in FIG. 7.

FIG. 9 is a plan view schematically showing a configuration example of scanning lines, semiconductors, and dummy semiconductors.

FIG. 10 is a schematic plan view showing another configuration example of the scanning lines and the dummy semiconductors.

FIG. 11 is a diagram showing an example of the shape of an identification symbol.

FIG. 12 is a cross-sectional view for illustrating the effect of the display device according to this embodiment.

FIG. 13 is a diagram showing another example of the shape of the identification symbol.

### DETAILED DESCRIPTION

In general, according to one embodiment, a display device includes a display area and a peripheral area on an outer side of the display area, a plurality of scanning lines extending along a first direction and arranged along a second direction intersecting the first direction, a first semiconductor layer disposed in the display area and overlapping a respective one of the plurality of scanning lines, and a second semiconductor layer disposed in the peripheral area and overlapping one of the plurality of scanning lines, and the second semiconductor layer includes a first dummy semiconductor patterned into a shape of an identification symbol.

According to another embodiment, a display device includes a display area, a peripheral area on an outer side of the display area, a plurality of scanning lines extending along a first direction and arranged along a second direction intersecting the first direction, a first semiconductor layer disposed in the display area and overlapping the plurality of scanning lines, and a second semiconductor layer disposed in the peripheral area and overlapping the plurality of scanning lines, and the second semiconductor layer includes a first segment overlapping one of a respective pair of those of the scanning lines, which are adjacent to each other along the second direction, and a second segment overlapping an other one of the respective pair of those of the scanning lines, which are adjacent to each other along the second direction, and separated from the first segment, and a combination of the first segment and the second segment constitutes a shape of an identification symbol.

According to the embodiments, it is possible to provide a display device which can achieve narrow frame design.

Several embodiments will be described with reference to the accompanying drawings.

Note that the disclosure is merely an example, and proper changes within the spirit of the invention, which are easily conceivable by a skilled person, are included in the scope of the invention as a matter of course. In addition, as to the drawings, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as an X direction (first direction), a direction along the Y axis is referred to as a Y direction (second direction) and a direction along the Z axis is referred to as a Z direction (third direction). Further, viewing the constitutional elements parallel to the Z direction is referred to as plan view.

The display device according to each embodiment is an organic electroluminescence display device comprising organic light-emitting diodes (OLEDs) as display elements, and may be incorporated into various electronic devices such as televisions, personal computers, in-vehicle devices, tablet terminals, smartphones, mobile phone terminals, wearable devices and the like.

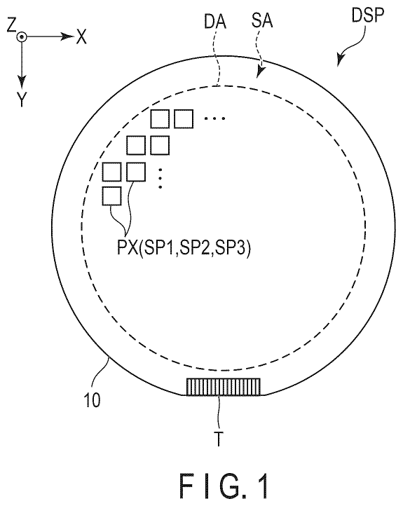

FIG. 1 is a diagram showing a configuration example of the display device DSP according to this embodiment. The display device DSP includes an insulating substrate 10. The substrate 10 has a display area DA which displays images and a peripheral area SA surrounding the display area DA. The substrate 10 may be glass or a flexible resin film. The Z direction corresponds to the thickness direction of the substrate 10.

In this embodiment, the shape of the substrate 10 in plan view is circular. Note that the shape of the substrate 10 in plan view is not limited to circular and may be some other shape such as rectangular, square, or elliptical.

The display area DA comprises a plurality of pixels PX arranged in a matrix along the X direction and Y direction. Each of the pixels PX includes a plurality of subpixels SP that display different colors. In this embodiment, it is assumed that the pixels PX each contain a green subpixel SP1, a blue subpixel SP2, and a red subpixel SP3. Note here that the pixels PX each may as well contain a subpixel SP of another color such as white, in addition to the subpixels SP1, SP2, and SP3, or in place of any of the subpixels SP1, SP2, and SP3.

The display device DSP further includes a terminal portion T disposed in the peripheral area SA. To the terminal portion T, a flexible circuit board which supplies, for example, voltage and signals for driving the display device DSP, is connected.

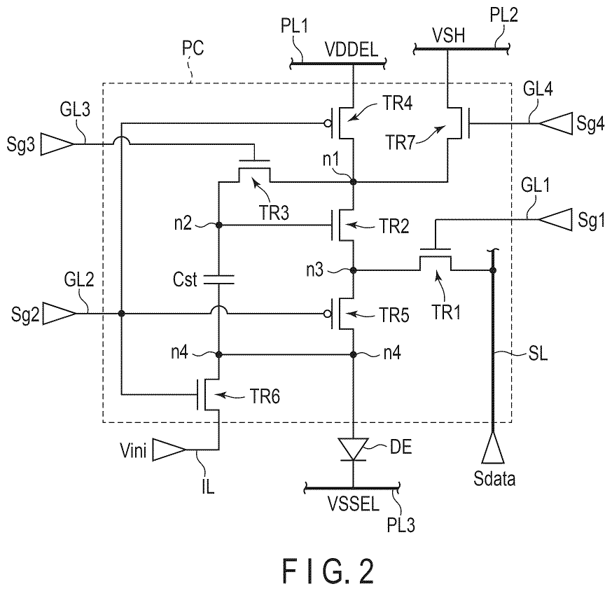

FIG. 2 is a circuit diagram showing a configuration example applicable to a pixel circuit PC provided for each of the subpixels SP (SP1, SP2, and SP3). The pixel circuit PC shown in this figure includes seven transistors TR1 to TR7 and one storage capacitor Cst.

In the following description, one of the source/drain electrodes of each of the transistors TR1 to TR7 is referred to as a first electrode, and the other is referred to as a second electrode. Similarly, one of the electrodes of the storage capacitor Cst is referred to as the first electrode, and the other electrode is referred to as the second electrode.

The first electrode of the transistor TR1 is connected to a node n3. The second electrode of the transistor TR1 is connected to a signal line SL, which supplies an image signal Sdata. The image signal Sdata is a signal to be written to the pixels for image display.

The transistor TR2 corresponds to a drive transistor that supplies current to the display element DE contained within the subpixel SP. The first electrode of the transistor TR2 is connected to the node n1. The second electrode of the transistor TR2 is connected to a node n3.

The first electrode of the transistor TR3 is connected to the node n1. The second electrode of the transistor TR3 is connected to a node n2.

The first electrode of the transistor TR4 is connected to the node n1. The second electrode of the transistor TR4 is connected to a power line PL1, which supplies a power supply voltage VDDEL.

The first electrode of the transistor TR5 is connected to the node n3. The second electrode of the transistor TR5 is connected to a node n4.

The first electrode of the transistor TR6 is connected to the node n4. The second electrode of the transistor TR6 is connected to an initialization line IL, which supplies an initialization voltage Vini.

The first electrode of the transistor TR7 is connected to the node n1. The second electrode of the transistor TR7 is connected to a power line PL2, which supplies a power supply voltage VSH.

The first electrode of the storage capacitor Cst is connected to the node n2. The second electrode of the storage capacitor Cst is connected to the node n4.

The gate electrode of the transistor TR1 is connected to a scanning line GL1, which supplies a scanning signal Sg1. The gate electrodes of the transistors TR4, TR5, and TR6 are connected to a scanning line GL2, which supplies a scanning signal Sg2. The gate electrode of the transistor TR3 is connected to a scanning line GL3, which supplies a scanning signal Sg3. The gate electrode of the transistor TR7 is connected to a scanning line GL4, which supplies a scanning signal Sg4.

The node n4 is connected to the anode of the display element DE. The cathode of the display element DE is connected to a power line PL3, which supplies a power supply voltage VSSEL. The power supply voltage VDDEL described above corresponds to the anode voltage supplied to the display element DE, and the power supply voltage VSSEL corresponds to the cathode voltage supplied to the display element DE.

Note that the configuration of the pixel circuit PC is not limited to that of the example shown in FIG. 2. For example, the pixel circuit PC may as well include six or fewer transistors, or eight or more transistors. Further, the pixel circuit PC may include multiple storage capacitors Cst.

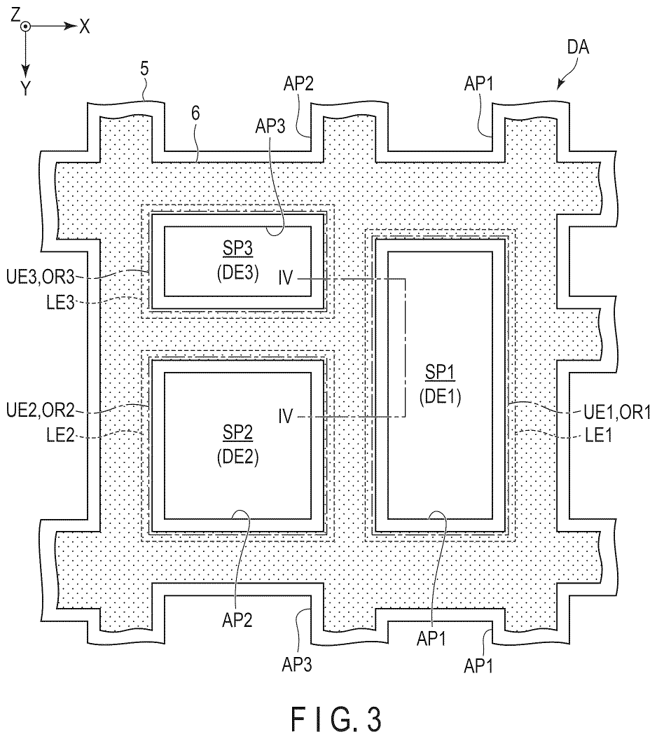

FIG. 3 is a schematic plan view showing an example of the layout of the subpixels SP1, SP2, and SP3. In the example of FIG. 3, the subpixels SP2 and SP3 are each aligned with the subpixel SP1 along the X direction. Further, the subpixels SP2 and SP3 are arranged along the Y direction.

When the subpixels SP1, SP2, and SP3 are arranged in such a layout, columns in each of which the subpixels SP2 and SP3 are alternately disposed along the Y direction and columns in each of which the plurality of subpixels SP1 are repeatedly disposed along the Y direction in the display area DA. These columns are alternately arranged along the X direction. Note that the layout of the subpixels SP1, SP2, and SP3 is not limited to that of the example in FIG. 3.

In the display area DA, a rib layer 5 is disposed. The rib layer 5 includes pixel apertures AP1, AP2, and AP3 in subpixels SP1, SP2, and SP3, respectively. In the example of FIG. 3, the pixel aperture AP1 is larger than the pixel aperture AP2, and the pixel aperture AP2 is larger than the pixel aperture AP3. That is, of the subpixels SP1, SP2, and SP3, the subpixel SP1 has the largest aperture ratio, and the subpixel SP3 has the smallest aperture ratio. The size and shape of the pixel apertures AP1, AP2, and AP3 are not limited to those of the example illustrated above.

The subpixel SP1 includes a lower electrode LE1, an upper electrode UE1, and an organic layer OR1, each overlapping the pixel aperture AP1. The subpixel SP2 includes a lower electrode LE2, an upper electrode UE2, and an organic layer OR2, each overlapping the pixel aperture AP2. The subpixel SP3 includes a lower electrode LE3, an upper electrode UE3, and an organic layer OR3, each overlapping the pixel aperture AP3.

The parts of the lower electrode LE1, upper electrode UE1, and organic layer OR1, which overlap the pixel aperture AP1 constitute the display element DE1 of the subpixel SP1. The parts of the lower electrode LE2, upper electrode UE2, and organic layer OR2, which overlap the pixel aperture AP2 constitute the display element DE2 of the subpixel SP2. The parts of the lower electrode LE3, upper electrode UE3, and organic layer OR3, which overlap the pixel aperture AP3 constitute the display element DE3 of the sub-pixel SP3. The display elements DE1, DE2, and DE3 may further include a cap layer, which will be described later. The rib layer 5 surrounds each of these display elements DE1, DE2, and DE3.

In the display area DA, a conductive partition 6 is disposed. The partition 6 is located above the rib layer 5 and overlaps the rib layer 5 entirely. In the example of FIG. 3, the partition 6 has a planar shape similar to that of the rib layer 5. That is, the partition 6 has an aperture at each of the subpixels SP1, SP2, and SP3. From another perspective, the rib layer 5 and the partition 6 are of a gride-like shape in plan view and surround each of the display elements DE1, DE2, and DE3. The partition 6 functions as a wiring portion which supplies a common voltage to the upper electrodes UE1, UE2, and UE3.

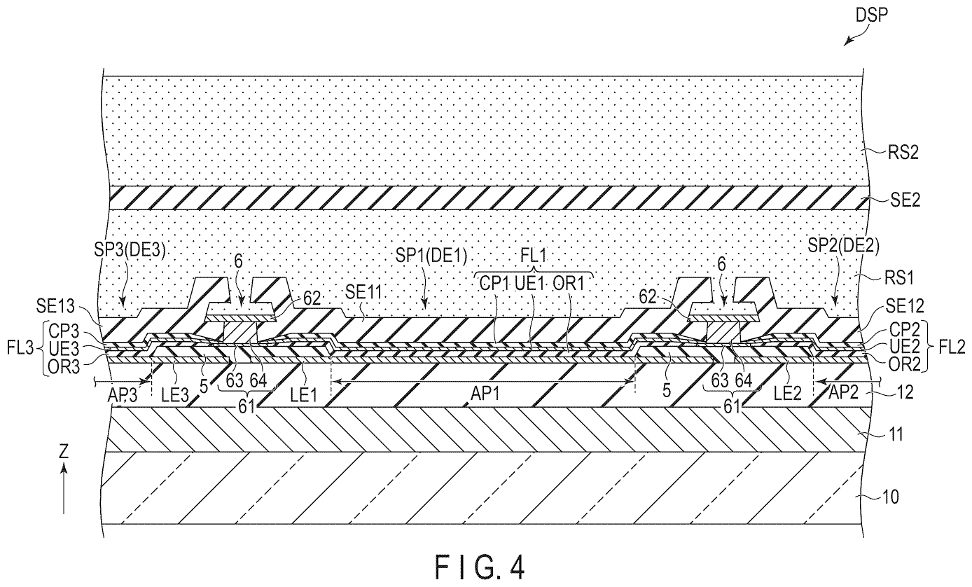

FIG. 4 is a schematic cross-sectional view of the display device DSP taken along the line IV-IV in FIG. 3. On top of substrate 10 described above, a circuit layer 11 is arranged. The circuit layer 11 contains various circuits and wiring lines such as the pixel circuit PC, scanning lines GL1 to GL4, signal lines SL, power lines PL1 to PL3, and initialization line IL, as shown in FIG. 2. The circuit layer 11 is covered by the organic insulating layer 12. The organic insulating layer 12 functions as a planarization film that planarizes the unevenness created by the circuit layer 11.

The lower electrodes LE1, LE2, and LE3 are disposed on the organic insulating layer 12 and are spaced apart from each other. The rib layer 5 is disposed on the organic insulating layer 12 and the lower electrodes LE1, LE2, and LE3. The peripheral portions of the lower electrodes LE1, LE2, and LE3 are covered by the rib layer 5. Although not shown in the cross-sectional view of FIG. 4, the lower electrodes LE1, LE2, and LE3 are each connected to the pixel circuit PC of the circuit layer 11 through contact holes provided in the organic insulating layer 12.

The partition 6 includes a conductive lower portion 61 disposed on the rib layer 5, and an upper portion 62 disposed on the lower portion 61. The upper portion 62 has a width greater than that of the lower portion 61. With this configuration, both end portions of the upper portion 62 protrude beyond the respective side surfaces of the lower portion 61. Such a shape of the partition 6 is referred to as an overhanging shape.

In the example of FIG. 4, the lower portion 61 includes a bottom layer 63 disposed on the rib layer 5 and a stem layer 64 disposed on the bottom layer 63. For example, the bottom layer 63 is formed thinner than the stem layer 64. In the example of FIG. 4, both end portions of the bottom layer 63 protrude beyond the respective side surfaces of the stem layer 64. Further, the end portions of the bottom layer 63 are positioned, in plan view, between the respective end portions of the upper portion 62 and the respective side surfaces of the stem layer 64. The upper portion 62 is disposed on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers to improve the light extraction efficiency of light emitted from the organic layers OR1, OR2, and OR3, respectively.

In the following descriptions, the stacked multilayer body including the organic layer OR1, upper electrode UE1, and cap layer CP1 is referred to as a stacked multilayer film FL1, the stacked multilayer structure including the organic layer OR2, upper electrode UE2, and cap layer CP2 is referred to as a stacked multilayer film FL2, and the stacked multilayer structure including the organic layer OR3, upper electrode UE3, and cap layer CP3 is referred to as a stacked multilayer film FL3.

In the subpixels SP1, SP2, and SP3, sealing layers SE11, SE12, and SE13, which respectively cover the stacked multilayer films FL1, FL2, and FL3, are disposed. The sealing layer SE11 continuously covers the display element DE1 and the surrounding part of the partition 6. The sealing layer SE12 continuously covers the display element DE2 and the surrounding part of the partition 6. The sealing layer SE13 continuously covers the display element DE3 and the surrounding part of the partition 6.

In the example of FIG. 4, the sealing layer SE11 on the partition 6 between the subpixels SP1 and SP2 is spaced apart from the sealing layer SE12 on the partition 6. Further, the sealing layer SE11 on the partition 6 between the subpixels SP1 and SP3 is spaced apart from the sealing layer SE13 on the partition 6.

Note that any two of the sealing layers SE11, SE12, and SE13 may be brought into contact with each other above the partition 6.

For example, between the sealing layers SE11, SE12, SE13 and the upper portion 62 of the partition 6, gaps are formed. The stacked multilayer films FL1, FL2, FL3 may be disposed in at least parts of these gaps.

The sealing layers SE11, SE12, SE13 are covered by the resin layer RS1. The resin layer RS1 is covered by the sealing layer SE2. The sealing layer SE2 is covered by the resin layer RS2. The resin layers RS1, RS2, and the sealing layer SE2 are continuously provided over at least the entire display area DA, and a part thereof extends even the peripheral area SA. In FIG. 4, elements above the resin layer RS2 are omitted.

The organic insulating layer 12 is formed from an organic insulating material such as polyimide. The rib layer 5 and the sealing layers SE11, SE12, SE13, and SE2 are formed from inorganic insulating materials such as silicon nitride (SiNx), silicon oxide (SiOx), and silicon oxynitride (SiON). In one example, the rib layer 5 is formed of silicon oxynitride, and the sealing layers SE11, SE12, SE13, SE2 are formed from silicon nitride. The resin layers RS1 and RS2 are formed from a resin material (organic insulating material), such as epoxy resin or acrylic resin.

The lower electrodes LE1, LE2, and LE3 each include a reflective layer and a pair of conductive oxide layers which covers each of the upper and lower surfaces of the reflective layer. The reflective layer can be formed from a metal material having excellent light reflectivity, such as silver. Each of the conductive oxide layers is formed from, for example, a transparent conductive oxide such as indium tin oxide (ITO), indium zinc oxide (IZO), or indium gallium zinc oxide (IGZO).

The upper electrodes UE1, UE2, and UE3 are formed from a metal material such as magnesium-silver alloy (MgAg). For example, the lower electrodes LE1, LE2, and LE3 correspond to the anodes, while the upper electrodes UE1, UE2, UE3 correspond to the cathodes.

The cap layers CP1, CP2, and CP3 may have a stacked multilayer structure in which multiple transparent layers are stacked one on another. These transparent layers may include layers formed from inorganic materials and layers formed from organic materials. Further, these transparent layers may have refractive indices different from each other. For example, the refractive indices of these transparent layers differ from the refractive indices of the upper electrodes UE1, UE2, and UE3 and those of the sealing layers SE11, SE12, and SE13. Note that at least one of the cap layers CP1, CP2, CP3 may be omitted.

The bottom layer 63 and stem layer 64 of the partition 6 are formed, for example, from a metal material. As the metal material for the bottom layer 63, for example, molybdenum (Mo), titanium (Ti), titanium nitride (TiN), molybdenum-tungsten alloy (MoW), or molybdenum-niobium alloy (MoNb) can be used. The metal material for the stem layer 64 may be, for example, aluminum (Al), aluminum-neodymium alloy (AlNd), aluminum-yttrium alloy (AlY), or aluminum-silicon alloy (AlSi). Note that at least one of the bottom layer 63 and the stem layer 64 may have a stacked multilayer structure constituted by multiple layers. Further, the stem layer 64 may also include a layer formed of an insulating material.

For example, the upper portion 62 of the partition 6 has a stacked multilayer structure constituted by a lower layer formed of a metal material and an upper layer formed of a conductive oxide. The metal material used for forming the lower layer may be, for example, titanium, titanium nitride, molybdenum, tungsten, a molybdenum-tungsten alloy, or a molybdenum-niobium alloy. The conductive oxide used for forming the upper layer may be, for example, ITO or IZO. Note that the upper portion 62 may also have a single-layer structure of a metal material. Further, the upper portion 62 may include a layer formed of an insulating material.

To the partition 6, a common voltage is supplied. The common voltage is supplied to each of the upper electrodes UE1, UE2, and UE3, which are in contact with the side surfaces of the lower portion 61. To the lower electrodes LE1, LE2, and LE3, pixel voltages corresponding to the image signals from the respective signal lines SL via the pixel circuits PC of the subpixels SP1, SP2, and SP3 are supplied.

In one example, the organic layers OR1, OR2, and OR3 are configured to emit light of different colors. In another example, the light-emitting layers of the organic layers OR1, OR2, and OR3 may emit light of the same color (for example, white). In this case, the display device DSP may include color filters that convert the light emitted by the light-emitting layers contained in the organic layers OR1, OR2, and OR3 into light of the respective colors corresponding to the subpixels SP1, SP2, and SP3. Further, the display device DSP may also include a layer containing quantum dots that are excited by the light emitted from the light-emitting layers and generate light of respective colors corresponding to the subpixels SP1, SP2, and SP3.

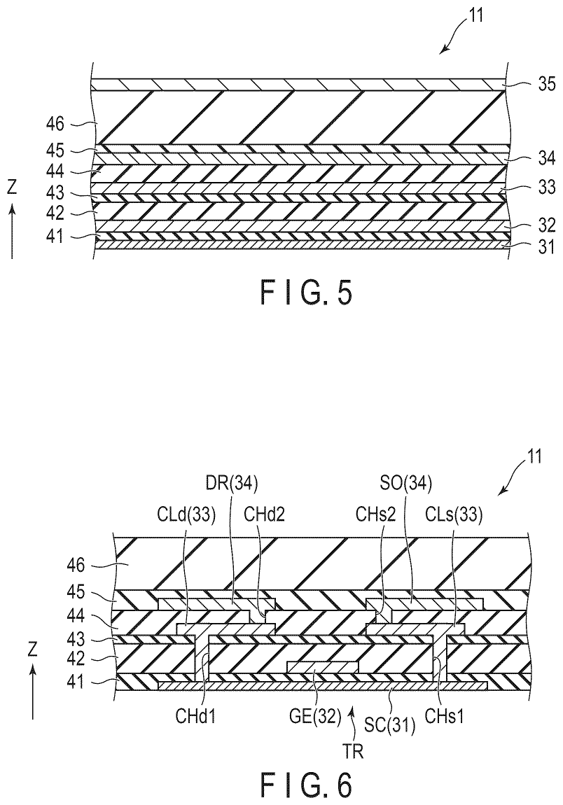

FIG. 5 is a schematic cross-sectional view showing an example of a layer configuration applicable to the circuit layer 11. In the example shown in FIG. 5, the circuit layer 11 comprises a semiconductor layer 31, metal layers 32, 33, 34, and 35, inorganic insulating layers 41, 42, 43, 44, and 45, and an organic insulating layer 46.

For example, the semiconductor layer 31 corresponds to the lowermost layer of the circuit layer 11. Note here that an insulating layer may be disposed below the semiconductor layer 31. The inorganic insulating layer 41 covers the semiconductor layer 31. The metal layer 32 is disposed on the inorganic insulating layer 41. The inorganic insulating layer 42 covers the metal layer 32. The inorganic insulating layer 43 covers the inorganic insulating layer 42. The metal layer 33 is disposed on the inorganic insulating layer 43. The inorganic insulating layer 44 covers the metal layer 33. The metal layer 34 is disposed on the inorganic insulating layer 44. The inorganic insulating layer 45 covers the metal layer 34. The organic insulating layer 46 covers the inorganic insulating layer 45. The metal layer 35 is disposed on the organic insulating layer 46 and is covered by the organic insulating layer 12 shown in FIG. 4.

The semiconductor layer 31 is formed, for example, from polysilicon, amorphous silicon, or an oxide semiconductor. To the metal layers 32 to 35, either a single-layer structure of a metal material or a stacked multilayer structure which uses multiple metal materials can be applied. In one example, the metal layers 32 and 33 are formed from molybdenum-tungsten alloy (MoW), whereas the metal layers 34 and 35 are formed as a stacked multilayer structure (so-called TAT) in which an aluminum layer is sandwiched between a pair of titanium layers.

The inorganic insulating layers 41 to 45 are each formed from an inorganic insulating material such as silicon nitride, silicon oxide, or silicon oxynitride. Further, the organic insulating layer 46 is formed from an organic insulating material such as polyimide so as to be thicker than the inorganic insulating layers 41 to 45.

Further, the signal lines SL, initialization line IL, power lines PL1 and PL2, and scanning lines GL1 to GL4 shown in FIG. 2 are formed from one of the metal layers 32 to 35. In one example, the scanning lines GL1 to GL4 are formed from at least one of the metal layers 32 and 33, the signal line SL and power line PL1 are formed from the metal layer 34, and the power line PL2 and initialization line IL are formed from the metal layer 35.

FIG. 6 is a diagram showing a configuration example of a transistor (TFT) included in the circuit layer 11. The transistor TR shown in FIG. 6 includes a semiconductor SC, a gate electrode GE, conductive layers CLs and CLd, a source electrode SO, and a drain electrode DR.

The semiconductor SC is covered by the inorganic insulating layer 41. The gate electrode GE is disposed on the inorganic insulating layer 41 and is covered by the inorganic insulating layer 42. The conductive layers CLs and CLd are spaced apart from each other, disposed on the inorganic insulating layer 43, and covered by the inorganic insulating layer 44. The source electrode SO and drain electrode DR are spaced apart from each other, disposed on the inorganic insulating layer 44, and covered by the inorganic insulating layer 45.

The conductive layer CLs is brought into contact with the semiconductor SC through contact holes CHs1 provided in the inorganic insulating layers 41, 42, and 43, respectively. The conductive layer CLd is brought into contact with the semiconductor SC through contact holes CHd1 provided in the inorganic insulating layers 41, 42, and 43, respectively. The source electrode SO is brought into contact with the conductive layer CLs through a contact hole CHs2 provided in the inorganic insulating layer 44. The drain electrode DR contacts the conductive layer CLd through a contact hole CHd2 provided in the inorganic insulating layer 44. Note that the source electrode SO and drain electrode DR may as well be brought into direct contact with the semiconductor SC through contact holes provided in the inorganic insulating layers 41 to 44, respectively.

The semiconductor SC is formed from the semiconductor layer 31. The gate electrode GE is formed from the metal layer 32. The conductive layers CLs and CLd are formed from the metal layer 33. The source electrode SO and drain electrode DR are formed from the metal layer 34. The configuration of the transistor TR can be applied to the transistors TR1 to TR7 shown in FIG. 2.

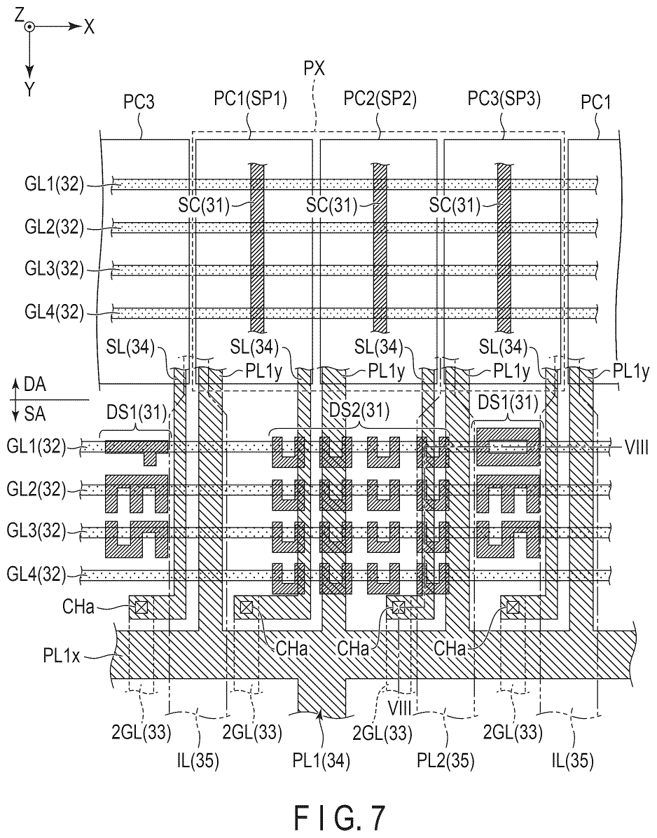

FIG. 7 is a schematic plan view showing an example of the boundary between the display area DA and the peripheral area SA. The example shown in FIG. 7 illustrates the boundary between the display area DA and the peripheral area SA on the terminal portion T side shown in FIG. 1.

In the display area DA, the pixels PX described above are arranged. The subpixels SP1, SP2, and SP3 included within the pixel PX comprise pixel circuits PC1, PC2, and PC3, respectively. In one example, the pixel circuits PC1, PC2, and PC3 are arranged along the X direction. The configuration of the pixel circuit PC shown in FIG. 2 can be applied to each of the pixel circuits PC1, PC2, and PC3. In the example shown in FIG. 7, the scanning lines GL1 to GL4 included in the pixel circuit PC extend in the X direction over the display area DA and peripheral area SA, and are arranged along the Y direction.

The semiconductor SC (first semiconductor layer) contained within each transistor of the pixel circuits PC1, PC2, and PC3 is disposed in the display area DA and overlaps with each of the scanning lines GL1 to GL4. In the example shown in FIG. 7, the semiconductor SC extends along the Y direction. Note that the semiconductor SC may as well have a shape that is bent at multiple locations, for example.

In the peripheral area SA, the scanning lines GL1 to GL4, 2GL, signal lines SL, power lines PL1 and PL2, initialization lines IL, dummy semiconductors DS1 and DS2 (second semiconductor layer), and the like are disposed. In one example, the scanning line 2GL is formed from the metal layer 33 shown in FIG. 5. The dummy semiconductors DS1 and DS2 are formed from the semiconductor layer 31 shown in FIG. 5. The dummy semiconductors DS1 and DS2 are formed of the same material as that of the semiconductor SC.

In FIG. 7, the scanning lines GL1 to GL4 are shown with a dot pattern, whereas the signal lines SL, power lines PL1, and dummy semiconductors DS1 and DS2 are shown with a diagonal line pattern. Further, the outline of the scanning line 2GL is shown with a dashed line, and the outlines of the initialization line IL and power line PL2 are each shown with a dotted line.

The signal lines SL extend along the Y direction and are arranged along the X direction. The signal lines SL intersect the scanning lines GL1 to GL4. The scanning lines 2GL extend along the Y direction and are arranged along the X direction. The scanning lines 2GL are brought into contact with the signal lines SL through contact holes CHa, respectively.

The power lines PL1 include a power line PL1x extending along the X direction and multiple power lines PL1y extending from the power line PL1x into the display area DA along the Y direction and arranged along the X direction. In the example shown in FIG. 7, the power line PL1x overlaps with the scanning line 2GL, the power line PL2, and the initialization line IL. Each of the multiple power lines PL1y is disposed between each respective pair of signal lines SL adjacent to each other along the X direction. The signal line SL and power line PL1 overlap the display area DA and constitute the source electrode SO and drain electrode DR shown in FIG. 6.

The initialization line IL and power line PL2 extend along the Y direction. The initialization line IL and power line PL2 overlap the signal line SL and power line PL1, respectively.

The dummy semiconductor DS1 (first dummy semiconductor) is patterned into the shape of an identification symbol. For the shape of the identification symbol, for example, a number or an alphabet can be applied. In the example shown in FIG. 7, the dummy semiconductor DS1 is patterned into the shape of an identification symbol of a numeral. The shape of the identification symbol of this numeral represents, for example, the wiring number of the signal line SL. The shape of identification symbol may as well represent, for example, the wiring number of the scanning line GL or the manufacturing lot number. Further, the wiring number may be represented by a single identification symbol or by a combination of multiple identification symbols. In the example shown in FIG. 7, the wiring number of the signal line SL is represented by three identification symbols.

The shape of the identification symbol can be read, for example, from the rear surface side of the display device DSP (the substrate 10 side shown in FIG. 4). Therefore, the identification symbol shown in FIG. 7 is displayed in a mirror image (horizontally flipped). Consequently, the three identification symbols shown on the right side of FIG. 7 represent “2”, “3”, and “0”, respectively, and the combination of these identification symbols represents “230”. Similarly, the three identification symbols shown on the left side of FIG. 7 represent “2”, “3”, and “1”, respectively, and the combination of these identification symbols represents “231”.

Each of the multiple dummy semiconductors DS1 overlaps with one of the scanning lines GL1 to GL4. In the example shown in FIG. 7, the dummy semiconductor DS1 representing “0 ” and “1” overlaps with the scanning line GL1, the dummy semiconductor DS1 representing “3” overlaps with the scanning line GL2, and the dummy semiconductor DS1 representing “2” overlaps with the scanning line GL3. Further, in the example shown in FIG. 7, the scanning line GL4 is not overlapping with any dummy semiconductor DS1.

The dummy semiconductor DS1 is disposed between the respective pair of signal lines SL adjacent to each other along the X direction. In the example shown in FIG. 7, the dummy semiconductor DS1 is disposed between the respective pair of signal lines SL adjacent to each other along the X direction and the power line PL1y.

Each of the multiple dummy semiconductors DS2 (second dummy semiconductors) overlaps with one of the scanning lines GL1 to GL4. In the example shown in FIG. 7, four dummy semiconductors DS2 overlap with each of the scanning lines GL1 to GL4. Further, the multiple dummy semiconductors DS2 are arranged in a matrix pattern. The dummy semiconductors DS2 are spaced apart from the dummy semiconductors DS1 along the X direction.

In the example shown in FIG. 7, the multiple dummy semiconductors DS2 are formed into a U-shape.

Note that the shape of the multiple dummy semiconductors DS2 is not limited to the U-shape.

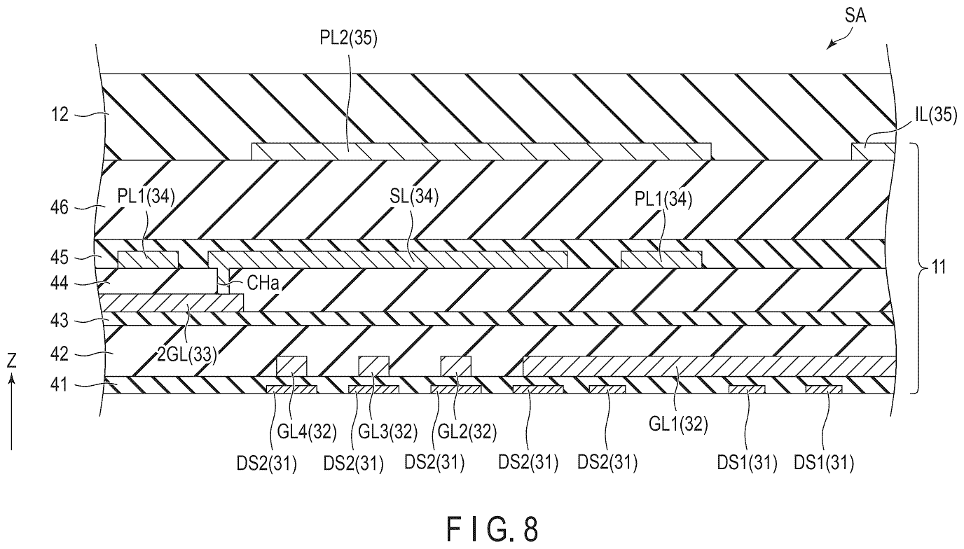

FIG. 8 is a schematic cross-sectional view of the display device DSP along the line VIII-VIII in FIG. 7.

The inorganic insulating layer 41 covers the dummy semiconductors DS1 and DS2. The scanning lines GL1 to GL4 are disposed on the inorganic insulating layer 41. The scanning lines GL1 to GL4 are disposed directly above the dummy semiconductors DS1 and DS2. In the example shown in FIG. 8, the scanning line GL1 is disposed directly above the dummy semiconductors DS1 and DS2, whereas the scanning lines GL2 to GL4 are each disposed directly above the dummy semiconductor DS2.

The inorganic insulating layer 42 covers the scanning lines GL1 to GL4. The scanning line 2GL is disposed on the inorganic insulating layer 43. The inorganic insulating layer 44 covers the scanning line 2GL. The signal line SL and power line PL1 are disposed on the inorganic insulating layer 44. The signal line SL is brought into contact with the scanning line 2GL through the contact hole CHa provided in the inorganic insulating layer 44.

The inorganic insulating layer 45 covers the signal lines SL and power lines PL1. The power lines PL2 and initialization lines IL are disposed on the organic insulating layer 46. The organic insulating layer 12 covers the power lines PL2 and initialization lines IL.

The dummy semiconductors DS1 and DS2 are formed from the semiconductor layer 31 and are located in the same layer as that of the semiconductor SC shown in FIG. 6. The scanning lines GL1 to GL4 are formed from the metal layer 32 and are located in the same layer as that of the gate electrode GE shown in FIG. 6. The scanning lines 2GL are formed from the metal layer 33. The signal lines SL and power lines PL1 are formed from the metal layer 34 and are located on the same layer as that of the source electrode SO and drain electrode DR shown in FIG. 6. The power lines PL2 and initialization lines IL are formed from the metal layer 35.

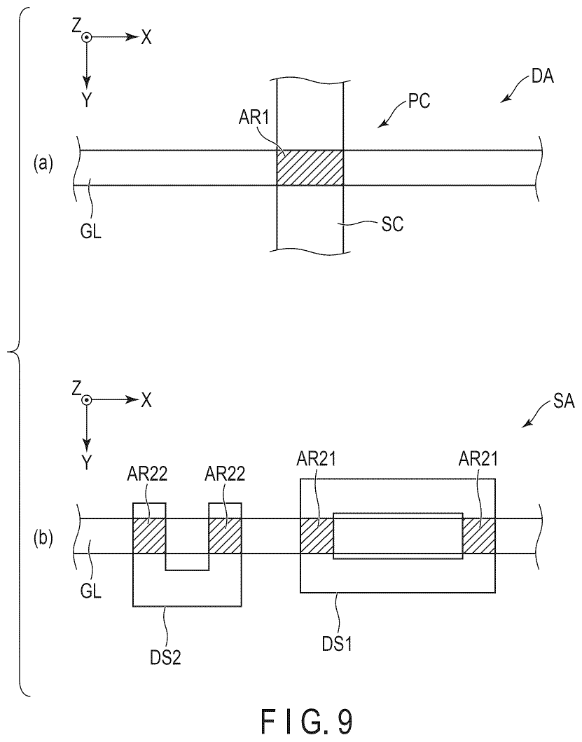

FIG. 9 is a schematic plan view showing a configuration example of a scanning line GL, a semiconductor SC, and dummy semiconductors DS1 and DS2. FIG. 9, in part (a), shows a scanning line GL and a semiconductor SC in the display area DA. FIG. 9, in part (b), shows a scanning line GL and dummy semiconductors DS1 and DS2 in the peripheral area SA. The scanning line GL corresponds to one of the scanning lines GL1 to GL4 shown in FIG. 7.

As shown in FIG. 9, part (a), the scanning line GL overlaps with the semiconductor SC in the display area DA. Hereinafter, the area where the scanning line GL overlaps with the semiconductor SC is referred to as area AR1.

As shown in FIG. 9, part (b), the scanning line GL overlaps with the dummy semiconductors DS1 and DS2 in the peripheral area SA. Hereinafter, the areas where the scanning line GL overlaps with the dummy semiconductor DS1 are referred to as areas AR21, respectively, and the areas where the scanning line GL overlaps with the dummy semiconductor DS2 are referred to as areas AR22, respectively. In the example of FIG. 9, part (b), the dummy semiconductor DS1 intersects the scanning line GL at two points, and the dummy semiconductor DS2 intersects the scanning line GL at two points.

At this time, the size of the respective one of the areas AR21 and the areas AR22 is less than or equal to that of the area AR1. In the example shown in FIG. 9, the size of the respective one of the areas AR21 and the areas AR22 is smaller than that of the area AR1.

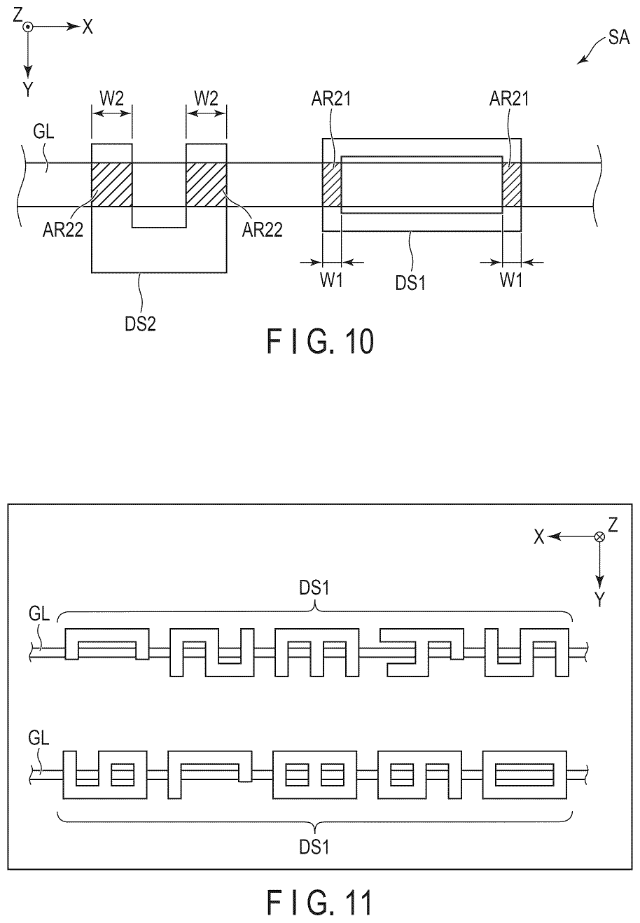

FIG. 10 is a schematic plan view showing another configuration example of a scanning line GL and dummy semiconductors DS1 and DS2. Here, the width along the X direction of the portion of the dummy semiconductor DS1, which extends along the Y direction and intersects the scanning line GL is referred to as a width W1. The width along the X direction of the portion of the dummy semiconductor DS2, which extends along the Y direction and intersects the scanning line GL is referred to as a width W2. In the example shown in FIG. 10, the width W1 is less than the width W2. Consequently, the area AR21 is smaller than the area AR22.

FIG. 11 is a diagram showing an example of the shape of identification symbols. In the example shown in FIG. 11, the identification symbols in the upper row represent “1 to 5” from left to right, respectively, and the identification symbols in the lower row represent “6 to 9” and “0 ” from left to right, respectively. Note that FIG. 11 shows the identification symbols as viewed from the rear side of the display device DSP.

In the example shown in FIG. 11, each of the dummy semiconductors DS1 intersects the scanning line GL at two or more points. Specifically, the dummy semiconductors DS1, patterned into the identification symbols representing “1”, “4”, “7”, “0”, respectively, intersect the scanning line GL at two points, and the dummy semiconductors DS1, patterned into the identification symbols representing “2”, “3”, “5”, “6”, “8” and “9”, respectively, intersect the scanning line GL at three points.

By combining these identification symbols, the wiring numbers of the signal lines SL shown in FIG. 7 can be expressed.

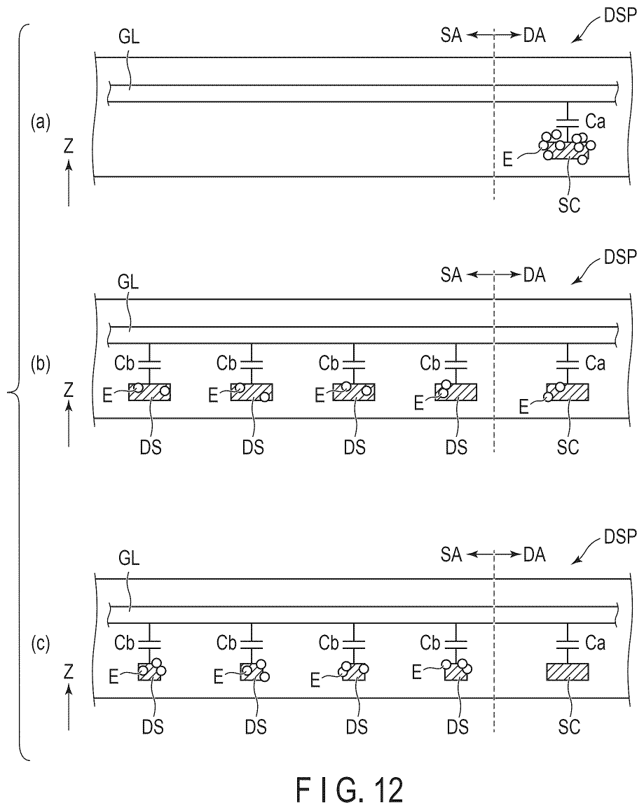

Next, the effects exhibited by the display device DSP according to this embodiment will be described. FIG. 12 is a cross-sectional view illustrating the effects of the display device DSP according to this embodiment. Hereinafter, the dummy semiconductors DS1 and DS2 will be collectively referred to as dummy semiconductors DS. Further, the capacitance formed between the semiconductor SC and the scanning line GL is referred to as a capacitance Ca, and the capacitance formed between the dummy semiconductor DS and the scanning line GL is referred to as a capacitance Cb.

FIG. 12, part (a), is a cross-sectional view of the display device DSP of the case where the device does not include dummy semiconductors DS in the peripheral area SA. In this case, charge E accumulated on the scanning lines GL during the manufacturing process of the display device DSP may be concentrated on the semiconductors SC in the display area DA, which may potentially cause damage to the semiconductors SC and the like, due to electrostatic discharge.

FIG. 12, part (b), is a cross-sectional view of the display device DSP of the case where the display device DSP includes dummy semiconductors DS in the peripheral area SA. Note that FIG. 12, part (b), shows the case where the capacitances Ca and Cb are equal to each other. In this case, the charge E accumulated in the scanning lines GL is evenly distributed between the semiconductors SC and the dummy semiconductors DS. Therefore, compared to the case where the display device DSP does not include the dummy semiconductors DS, it is possible to suppress the occurrence of damage due to electrostatic discharge.

Incidentally, for the display device DSP of such a type, there is a demand of achieving narrow bezels. But, when placing identification symbols each between each adjacent pair of the scanning lines GL1 to GL4, the intervals between the scanning lines GL1 to GL4 must be increased to accommodate the identification symbols, and therefore it is difficult to achieve narrow bezels.

If the intervals between the respective scanning lines GL1 to GL4 are reduced to achieve narrow bezels, the semiconductor layer 31 patterned into the shape of the identification symbols may possibly overlap with multiple ones of the scanning lines GL1 to GL4. As a result, multiple scanning lines overlapping the semiconductor layer 31 may cause a risk of short-circuiting through the semiconductor layer 31.

In this embodiment, the dummy semiconductor DS1, which is obtained by patterning the semiconductor layer 31 into the shape of the identification symbols, is placed in the peripheral area SA. Further, the dummy semiconductor DS1 overlaps with one of the scanning lines GL1 to GL4. With this configuration, there is no longer need to secure space for placing the identification symbols between the respective scanning lines GL1 to GL4, and thus the intervals between the scanning lines GL1 to GL4 can be reduced. Consequently, it is possible to achieve a narrow bezel for the display device DSP.

Further, by disposing the dummy semiconductor DS1 to overlap with a single scanning line GL, the risk of short-circuiting can be reduced. Moreover, by forming the identification symbols with the dummy semiconductor DS1, as shown in FIG. 12(b), damage to the semiconductors SC and the like, caused by electrostatic discharge, can be suppressed. As a result, it is possible to suppress the reduction in the manufacturing yield of the display device DSP and improve the reliability of the display device DSP.

FIG. 12, part (c), is a cross-sectional view of the display device DSP when the capacitance Cb is smaller than the capacitance Ca. In this case, the charge E moves to the site where the capacitance is smaller. Therefore, the charge E is concentrated on the dummy semiconductor DS in the peripheral area SA where the capacitance Cb, which is smaller than the capacitance Ca, is formed. With this configuration, compared to the case where the capacitances Ca and Cb are equal to each other, it is possible to more effectively suppress the occurrence of damage to the semiconductor SC and the like, caused by electrostatic discharge.

Here, the magnitude of the capacitance Cb is proportional to the area of the region where the scanning line GL and the dummy semiconductor DS overlap with each other. That is, as the area of the region where the scanning line GL and the dummy semiconductor DS overlap becomes smaller, the magnitude of the capacitance Cb becomes smaller. In this embodiment, as shown in FIG. 9, the sizes of the areas AR21 and AR22, where the scanning line GL overlaps with the dummy semiconductors DS1 and DS2, respectively, are smaller than the area AR1 where the scanning line GL overlaps with the semiconductor SC. Thus, the occurrence of breakdown due to electrostatic discharge can be further suppressed.

Furthermore, as shown in FIG. 10, by making the width W1 of the dummy semiconductor DS1 less than the width W2 of the dummy semiconductor DS2, and by making the size of the area AR21 smaller than the size of the area AR22, it is possible to further suppress the occurrence of breakdown due to electrostatic discharge.

Moreover, as the number of intersections between the scanning line GL and the dummy semiconductors DS1 and DS2 increases, the amount of charge E accumulating on the semiconductor SC decreases. Based on this, as shown in FIG. 11, by setting the identification symbols such that the scanning line GL intersects with the dummy semiconductor DS1 at two or more locations, it is possible to further suppress the breakdown caused by electrostatic discharge.

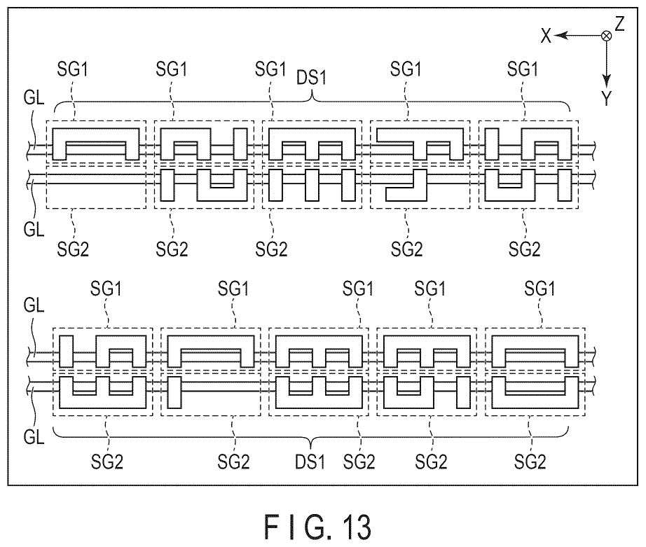

FIG. 13 shows another example of the shape of the identification symbols. In the example shown in FIG. 13, the identification symbols in the upper row represent “1 to 5” from left to right, respectively, and the identification symbols in the lower row represent “6 to 9” and “0 ” from left to right, respectively. Note that FIG. 13 shows the identification symbols as viewed from the rear side of the display device DSP.

Here, the dummy semiconductor DS1 overlapping one of two scanning lines GL adjacent to each other along the Y direction is defined as a first segment SG1, and the dummy semiconductor DS1 overlapping the other of the two scanning lines GL adjacent to each other along the Y direction is defined as a second segment SG2. In the example shown in FIG. 13, the dummy semiconductor DS1 overlapping the upper scanning line GL corresponds to the first segment SG1, and the dummy semiconductor DS1 overlapping the lower scanning line GL corresponds to the second segment SG2. The first segment SG1 and the second segment SG2 are spaced apart from each other.

In the example shown in FIG. 13, the shape of identification symbols is formed by the combination of the first segment SG1 and the second segment SG2. For example, the identification symbol representing “0 ” is formed by the combination of the first segment SG1 and the second segment SG2, which are formed into a C-shape.

Note that in the example shown in FIG. 13, the identification symbol representing “1” is formed solely by the first segment SG1, but it may as well be formed by a combination of the first segment SG1 and the second segment SG2. Further, the identification symbols are not limited to numerals.

Meanwhile, by dividing the identification symbols into the first segment SG1 and the second segment SG2, the interval between scanning lines GL adjacent to each other along the Y direction can be narrowed. With this configuration, the bezel area of the display device DSP can be made narrower.

Furthermore, in the example shown in FIG. 13, the first segment SG1 of the shape of the identification symbols, representing “1”, “2”, “3”, “4”, “5”, “6”, “7”, “8”, “9”, and “0”, respectively, intersects the scanning line GL at two or more points. Similarly, the second segment SG2 of the shape of the identification symbols, representing “2”, “3”, “5”, “6”, “8”, “9”, and “0 ” respectively, intersects the scanning line GL at two or more points.

By dividing the identification symbols into the first segment SG1 and the second segment SG2 in the above-described manner, the number of points where the scanning line GL intersects with the dummy semiconductor DS1 can be increased. With this configuration, it becomes possible to further suppress the occurrence of destruction due to electrostatic discharge.

Based on the display devices described above as embodiments of the invention, a person having ordinary skill in the art may achieve display devices, mother boards and manufacturing devices with arbitral design changes; however, as long as they fall within the scope and spirit of the present invention, all of such display devices are encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is

1. A display device comprising:
a display area;
a peripheral area on an outer side from the display area;
a plurality of scanning lines extending along a first direction and arranged along a second direction intersecting the first direction;
a first semiconductor layer disposed in the display area, and overlapping the plurality of scanning lines; and
a second semiconductor layer disposed in the peripheral area, and overlapping one of the plurality of scanning lines,
wherein
the second semiconductor layer includes a first dummy semiconductor patterned into a shape of an identification symbol.

2. The display device of claim 1, further comprising:
a plurality of signal lines extending along the second direction and arranged along the first direction,
wherein
the shape of the identification symbol represents a wiring number of a respective one of the scanning lines or the signal lines.

3. The display device of claim 1, wherein
an area of a region where a respective one of the scanning lines and the second semiconductor layer overlap is less than an area of a region where the respective one of the scanning lines and the first semiconductor layer overlap.

4. The display device of claim 1, wherein
an area of a region where a respective one of the scanning lines and the first dummy semiconductor overlap is less than an area of a region where the respective one of the scanning lines and the first semiconductor layer overlap.

5. The display device of claim 1, wherein
the first dummy semiconductor intersects a respective one of the scanning lines at two or more locations.

6. The display device of claim 1, wherein
the second semiconductor layer includes a second dummy semiconductor spaced apart from the first dummy semiconductor along the first direction.

7. The display device of claim 6, wherein
an area of a region where a respective one of the scanning lines and the second dummy semiconductor overlap is less than an area of a region where the respective one of the scanning lines and the first semiconductor layer overlap.

8. The display device of claim 6, wherein
an area of a region where a respective one of the scanning lines and the first dummy semiconductor overlap is less than an area of a region where the respective one of the scanning lines and the second dummy semiconductor overlap.

9. The display device of claim 6, wherein
the second dummy semiconductor intersects a respective one of the scanning lines at two or more locations.

10. The display device of claim 6, wherein
a width along the first direction of a portion of the first dummy semiconductor, which extends along the second direction and intersects a respective one of the scanning lines is less than a width along the first direction of a portion of the second dummy semiconductor, which extends along the second direction and intersects the respective one of the scanning lines.

11. The display device of claim 1, further comprising:
a plurality of signal lines extending along the second direction and arranged along the first direction,
wherein
the first dummy semiconductor is disposed between a respective pair of those of the signal lines, which are adjacent to each other along the first direction.

12. The display device of claim 11, further comprising:
a plurality of power supply lines extending along the second direction and arranged along the first direction,
wherein
the first dummy semiconductor is disposed between a respective one of the signal lines and a respective one of the power supply lines, which are adjacent to each other along the first direction.

13. The display device of claim 1, wherein
the first semiconductor layer and the second semiconductor layer are located in a same layer.

14. A display device comprising:
a display area;
a peripheral area on an outer side of the display area;
a plurality of scanning lines extending along a first direction and arranged along a second direction intersecting the first direction;
a first semiconductor layer disposed in the display area and overlapping the plurality of scanning lines; and
a second semiconductor layer disposed in the peripheral area and overlapping the plurality of scanning lines,
wherein
the second semiconductor layer includes a first segment overlapping one of a respective pair of those of the scanning lines, which are adjacent to each other along the second direction, and a second segment overlapping an other one of the respective pair of those of the scanning lines, which are adjacent to each other along the second direction, and separated from the first segment, and
a combination of the first segment and the second segment constitutes a shape of an identification symbol.

15. The display device of claim 14, further comprising:
a plurality of signal lines extending along the second direction and arranged along the first direction,
wherein
the shape of the identification symbol represents a wiring number of a respective one of the scanning lines or the signal lines.

16. The display device of claim 14, wherein
the first segment and the second segment intersect the respective one of the scanning lines at two or more locations.

17. The display device of claim 14, wherein
the first semiconductor layer and the second semiconductor layer are located in a same layer.

18. The display device of claim 1, wherein
the first semiconductor layer and the second semiconductor layer are formed of a same material.

19. The display device of claim 1, wherein
each of the first semiconductor layer and the second semiconductor layer is formed of polysilicon, amorphous silicon, or an oxide semiconductor.

20. The display device of claim 1, further comprising:
a lower electrode disposed in the display area and disposed above the first semiconductor layer;
a rib layer formed of an inorganic material, having a pixel aperture overlapping the lower electrode and covering a peripheral portion of the lower electrode;
a partition including a lower portion disposed on the rib layer and having conductivity and an upper portion disposed on the lower portion and protruding from a side surface of the lower portion;
an organic layer covering the lower electrode through the pixel aperture; and
an upper electrode covering the organic layer and in contact with the lower portion.
